(19) United States
(12) Patent Application Publication
(10) Pub. No.: US 2025/0334198 A1
(43) Pub. Date: Oct. 30, 2025

(54) SPOOL VALVE

(71) Applicant: CKD CORPORATION, Komaki-shi, Aichi (JP)

(72) Inventors: Yasuhisa HIROSE, Komaki-shi (JP); Takahiro MINATANI, Komaki-shi (JP)

(73) Assignee: CKD CORPORATION, Komaki-shi, Aichi (JP)

(21) Appl. No.: 18/865,769

(22) PCT Filed: Nov. 24, 2023
(86) PCT No.: PCT/JP2023/042155

§ 371 Date: Nov. 14, 2024

(30) Foreign Application Priority Data
Dec. 2, 2022 (JP) 2022-193269

(51) Int. Cl. F16K 31/06; F16K 11/07

(52) U.S. Cl. CPC F16K 31/0613; F16K 11/07

(57) ABSTRACT

A sleeve includes a first surface treated portion treated with electroless nickel plating at least on both ends in an axial direction, in an inner circumferential surface thereof. The first surface treated portion has an inner diameter smaller than other portions of the inner circumferential surface by a film thickness of first plating, and slidably supports a spool valve element.

### CROSS-REFERENCE TO RELATED APPLICATIONS

This is a US national phase application based on the PCT International Patent Application No. PCT/JP2023/042155 filed on Nov. 24, 2023, and claiming the priority to Japanese Patent Application No. 2022-193269 filed on Dec. 2, 2022, the entire contents of which are incorporated by reference herein.

### TECHNICAL FIELD

The invention relates to a spool valve.

### BACKGROUND ART

In a RIE (Reactive Ion Etching) type plasma treatment device used for manufacturing semiconductors, an etching process is performed on a wafer by introducing process gas into a treatment vessel while the wafer is placed on a susceptor in the treatment vessel. For this etching process, two or more types of process gases are used and thus different treatment conditions for each type of process gas are set. The treatment conditions also include the temperature of wafer to be treated and thus the wafer temperature has to meet the treatment condition. For this purpose, the temperature of the susceptor that holds the wafer is controlled.

Herein, as the technique of controlling the temperature of the susceptor, a flow rate control unit for temperature regulation has been known, as disclosed in Patent Document 1, for regulating the temperature of the susceptor by circulating a fluid for temperature regulation to the susceptor. In this temperature-regulation flow rate control unit, the temperature of the temperature regulation fluid is controlled in a manner that a spool valve regulates a flow rate of a high-temperature fluid for increasing the temperature of the temperature regulation fluid and a flow rate of a low-temperature fluid for decreasing the temperature of the temperature regulation fluid.

As the spool valve to be used in the temperature-regulation flow rate control unit, a spool valve disclosed for example in Patent Documents 2 is known. This spool valve includes a cylindrical sleeve, and a spool valve element that slides inside the sleeve in the axial direction. Further, the sleeve has two or more input ports and two or more output ports, which communicate with the inside of the sleeve. The above-mentioned spool valve is configured such that the open area of each of the input ports and the output ports is adjusted by sliding of the spool inside the sleeve.

RELATED ART DOCUMENTS

### Patent Documents

Patent Document 1: Japanese unexamined patent application publication No. 2020-160731 (JP 2020-160731A)
Patent Document 2: Japanese unexamined patent application publication No. 2020-106123 (JP 2020-106123A)

### SUMMARY OF INVENTION

### Problems to be Solved by the Invention

However, the spool valve according to the above-described related arts would cause the following problems.

A gap between the outer circumferential surface of the spool valve element and the inner circumferential surface of the sleeve (hereinafter, simply referred to as a clearance) is designed to be uniform in the axial direction of the sleeve. However, since both the sleeve and the spool valve element are generally formed into their respective shapes by cutting, this cutting process may cause distortion of their shapes. In such a case, the clearance could not be uniform in the axial direction of the sleeve, which may cause the outer circumferential surface of the spool valve element and the inner circumferential surface of the sleeve to interfere with each other. In addition, since there is no control where such an interference occurs, the interference may occur at multiple places. The interference occurring at multiple places results in a decrease in the slidability of the spool valve element inside the sleeve. Furthermore, this interference leads to the occurrence of wear in the sleeve or the spool valve element, shortening the service life of the spool valve.

The present disclosure has been made to address the above problems and has a purpose to control an interference place where an outer circumferential surface of a spool valve element and an inner circumferential surface of a sleeve interfere with each other in order to suppress a decrease in slidability of the spool valve element and the occurrence of wear in the sleeve or spool valve element.

### Means of Solving the Problems

To achieve the above-mentioned purpose, a spool valve of one aspect of the present invention provides the following configurations.

(1) A spool valve comprises: a cylindrical sleeve, the sleeve including two or more input ports and two or more output ports, each communicating with inside of the sleeve; and a spool valve element that slides inside the sleeve in an axial direction of the sleeve, an open area of each of the input ports and the output ports being adjusted by sliding of the spool valve element, wherein at least one of the sleeve and the spool valve element comprises, at each of both end portions in the axial direction of the sleeve, a support portion for supporting the sliding of the spool valve element by reducing a gap between an inner circumferential surface of the sleeve and an outer circumferential surface of the spool valve element than at other portions. The term “gap” here is determined by dividing a difference between the diameter of the inner circumferential surface of the sleeve and the diameter of the outer circumferential surface of the spool valve element by 2, assuming that the spool valve element is located coaxially with the sleeve.

(2) In the spool valve described in (1), preferably, the sleeve includes a first surface treated portion treated with first plating in each of both end portions of the inner circumferential surface in the axial direction, and the first surface treated portion is the support portion.

(3) In the spool valve described in (1), preferably, the spool valve element includes a surface treated portion treated with electrolytic plating, in each of portions of the outer circumferential surface facing both end portions of the inner circumferential surface of the sleeve in the axial direction, and the surface treated portion is the support portion.

(4) In the spool valve described in (2), preferably, the support portion has a width of 1 mm or more in the axial direction, but 15% or less of a total length of the sleeve in the axial direction.

According to the spool valve described in (1), at least the sleeve or the spool valve element includes, at both end portions in the axial direction of the sleeve, the support portions for supporting the sliding of the spool valve element by making the gap between the inner circumferential surface of the sleeve and the outer circumferential surface of the spool valve element smaller than at other portions, so that the support portions can aggressively support the spool valve element. The term “support/supporting” here does not mean fixing the spool valve element, but simply guiding the sliding of the spool valve element without causing the interference of the spool valve element with the inner circumferential surface of the sleeve at any places other than the support portions. That is, the place where the outer circumferential surface of the spool valve element interferes with the inner circumferential surface of the sleeve is limited to the support portion or portions, and it is possible to suppress the occurrence of the interference at multiple places. This can suppress the decrease in slidability of the spool valve element and reduce the occurrence of wear in the sleeve or the spool valve element.

Preferably, the support portions are formed of the first surface treated portions with the first plating, provided in both end portions of the inner circumferential surface of the sleeve in the axial direction, as in the spool valve described in (2), or the support portions are formed of the surface treated portions with the electrolytic plating, provided in the portions of the outer circumferential surface of the spool valve element, facing the both end portions of the inner circumferential surface of the sleeve in the axial direction, as in the spool valve described in (3).

Further, when each of the support portions is formed of the first surface treated portion treated with the first plating as in the spool valve described in (2), preferably, the width of each support portion in the axial direction is 1 mm or more, but 15% or less of the total length of the sleeve in the axial direction, as in the spool valve described in (4). This is because if the width of each support portion in the axial direction is smaller than 1 mm, that is, if the surface area of each support portion that supports the spool valve element is small, the stress per unit area is large, which may cause wear of the support portion due to sliding of the spool valve element. Such a wear is undesirable because it may impede the sliding of the spool valve element. Furthermore, if the width of each support portion in the axial direction is smaller than 1 mm, it is undesirable because the surface treatment such as plating cannot be achieved with a stable quality. If the width of each support portion in the axial direction is more than 15% of the total length of the sleeve, that is, if the surface area of each support portion supporting the spool valve element is large, the spool valve element and the support portion may contact each other at many contact points due to processing strain that occurs in the spool valve element and the sleeve. If many contact points occur between the spool valve element and the support portion, the effect of suppressing the decrease in slidability of the spool valve element and the effect of suppressing the occurrence of wear in the sleeve or spool valve element could not be achieved sufficiently.

(5) In the spool valve described in (2), preferably, the spool valve element includes a second surface treated portion treated with second plating, on at least a portion of the outer circumferential surface facing the first surface treated portion, and the second plating has a hardness higher than a hardness of the first plating.

The outer circumferential surface of a spool valve element and the inner circumferential surface of a sleeve may be plated for the purpose of improving wear resistance and improving corrosion resistance. At that time, when the hardness of a plating film on the outer circumferential surface of the spool valve element and the hardness of a plating film on the inner circumferential surface of the sleeve are set equal, a galling phenomenon of the plating films may occur during sliding of the spool valve element. This galling phenomenon may decrease the slidability of the spool valve element and, at worst, lead to inability to slide. Under such circumstances, the inventors have experimentally confirmed that when the hardness of the second plating on the outer circumferential surface of the spool valve element is set higher than the hardness of the first plating on the inner circumferential surface of the sleeve as in the spool valve described in (5), it is possible to prevent the occurrence of the galling phenomenon, and hence suppress the decrease in slidability of the spool valve element.

(6) In the spool valve described in (5), preferably, the first plating is electroless plating, and the second plating is electrolytic plating.

For dimensional control of the gap between the outer circumferential surface (the outer diameter) of the spool valve element and the inner circumferential surface (the inner diameter) of the sleeve, it is important that the first surface treated portion and the second surface treated portion respectively have uniform film thicknesses. For finishing to specified inner and outer diameters after plating, a means for dimensional adjustment in post-processing, such as polishing a plated surface, may be adopted. At that time, the outer diameter of the spool valve element is easy to adjust by processing, such as outer diameter polishing, but the inner diameter of the sleeve is hard to process. Therefore, as in the spool valve described in (5), the outer circumferential surface of the spool valve element is treated with the electrolytic plating (the second plating) that is apt to have a non-uniform film thickness and the inner circumferential surface of the sleeve is treated with the electroless plating (the first plating) that is easy to have a uniform film thickness, so that the size of the gap can be controlled appropriately. Moreover, the inventors experimentally confirmed that the first plating and the second plating applied by a dissimilar material treatment could prevent the occurrence of the galling phenomenon during sliding of the spool valve element.

(7) In the spool valve described in one of (1) to (6), preferably, in a flow rate control unit for temperature regulation, that regulates a temperature of a susceptor provided in a semiconductor manufacturing device by circulating a temperature regulation fluid to the susceptor, the spool valve regulates an output flow rate of a low-temperature fluid for reducing the temperature of the temperature regulation fluid, the low-temperature fluid being inputted in a first input port, which is one of the two or more input ports, and outputted from a first output port, which is one of the two or more output ports, and an output flow rate of a high-temperature fluid for increasing the temperature of the temperature regulation fluid, the high-temperature fluid being inputted in a second input port, which is one of the two or more input ports, and outputted from a second output port, which is one of the two or more output ports,

to regulate the temperature of the temperature regulation fluid, and the gap excluding a reduced area by the support portions is 7 μm or more, but 55 μm or less.

To suppress fluid leakage (so-called internal leakage) due to the gap between the inner circumferential surface of the sleeve and the outer circumferential surface of the spool valve element, it is necessary to seal between the inner circumferential surface of the sleeve and the outer circumferential surface of the spool valve element. However, this sealing leads to decreased slidability of the spool valve element. The responsiveness is important for the spool valve used in the temperature-regulation flow rate control unit, and thus the decreased slidability of the spool valve element due to the sealing is undesirable. In order to reduce the internal leakage to the minimum without the sealing, it is conceivable to minimize the gap between the inner circumferential surface of the sleeve and the outer circumferential surface of the spool valve element. However, if the gap is too small, the sleeve and the spool valve element may interfere with each other, resulting in the decreased slidability of the spool valve element. Therefore, the spool valve element is supported by the support portions and additionally the gap between the outer circumferential surface of the spool valve element and the inner circumferential surface of the sleeve 222 excluding the first surface treated portions is set to 7 μm or more, but 55 μm or less, as in the spool valve described in (7). This configuration can suppress the internal leakage of the high-temperature fluid and the low-temperature fluid while ensuring the slidability of the spool valve element.

(8) In the spool valve described in (1), preferably, the sleeve includes the support portion formed with a reduced inner diameter, on each of both end portions of the inner circumferential surface in the axial direction, and a reduced amount of the inner diameter of the support portion is 4 μm or more, but 60 μm or less.

(9) In the spool valve described in (8), preferably, the support portion has a width in the axial direction that is 2% or more, but 15% or less of a total length of the sleeve in the axial direction.

According to the spool valve described in (8) or (9), the sleeve includes the support portions formed with a reduced inner diameter, on both end portions of the inner circumferential surface in the axial direction, so that the spool valve element can be aggressively supported by the support portions. Accordingly, the place where the spool valve element and the sleeve interfere with each other is limited to the support portion(s), and it is possible to suppress the occurrence of interference at multiple places. At that time, the reduced amount of the diameter of each support portion is preferably 4 μm or more, but 60 μm or less. This is because if the diameter reduction amount is less than 4 μm, the spool valve element is not sufficiently supported, which may cause interference at a place other than the support portions. In contrast, if the diameter reduction amount is more than 60 μm, the internal fluid leakage may occur between the inner circumferential surface of the sleeve and the spool valve element.

Further, the width of each support portion in the axial direction is preferably 2% or more, but 15% or less of the total length of the sleeve in the axial direction. This is because if the width of the support portion in the axial direction is less than 2% of the total length of the sleeve in the axial direction, that is, if the surface area of the support portion that supports the spool valve element is small, the stress per unit area is large, which may cause the occurrence of wear of the support portion due to sliding of the spool valve element. The occurrence of wear is not desirable because it may impede the sliding of the spool valve element. In addition, if the width of the support portion in the axial direction is less than 2% of the total length of the sleeve in the axial direction, it is undesirable because the surface treatment such as plating cannot be achieved with a stable quality. In contrast, if the width of the support portion in the axial direction is more than 15% of the total length of the sleeve in the axial direction, that is, if the surface area of the support portion that supports the spool valve element is large, the spool valve element and the support portion may contact each other at many contact points due to processing strain that occurs in the spool valve element and the sleeve. If many contact points occur between the spool valve element and the support portion, the effect of suppressing the decrease in slidability of the spool valve element and the effect of suppressing the occurrence of wear in the sleeve or spool valve element could not be achieved sufficiently.

### Effects of the Invention

The spool valve of the invention can suppress a decrease in slidability of the spool valve element and suppress the occurrence of wear in the sleeve or spool valve element by controlling an interference place where the outer circumferential surface of the spool valve element and the inner circumferential surface of the sleeve interfere with each other.

### BRIEF DESCRIPTION OF THE DRAWINGS

FIG. 1 is a circuit diagram of a flow rate control unit for temperature regulation using a spool valve according to a first embodiment;

FIG. 2 is a cross-sectional view of the spool valve;

FIG. 3 is a partial enlarged view of a part A in FIG. 2;

FIG. 4 is a cross-sectional view showing the shape of a sleeve;

FIG. 5 is a partial enlarged view of a spool valve according to a second embodiment, similar to FIG. 3; and

FIG. 6 is a cross-sectional view of a spool valve according to a third embodiment, showing the shape of a sleeve.

### MODE FOR CARRYING OUT THE INVENTION

### First Embodiment

A first embodiment of a spool valve 21 according to invention will be described referring to the accompanying drawings.

### Outline Configuration of Flow Rate Control Unit for Temperature Regulation

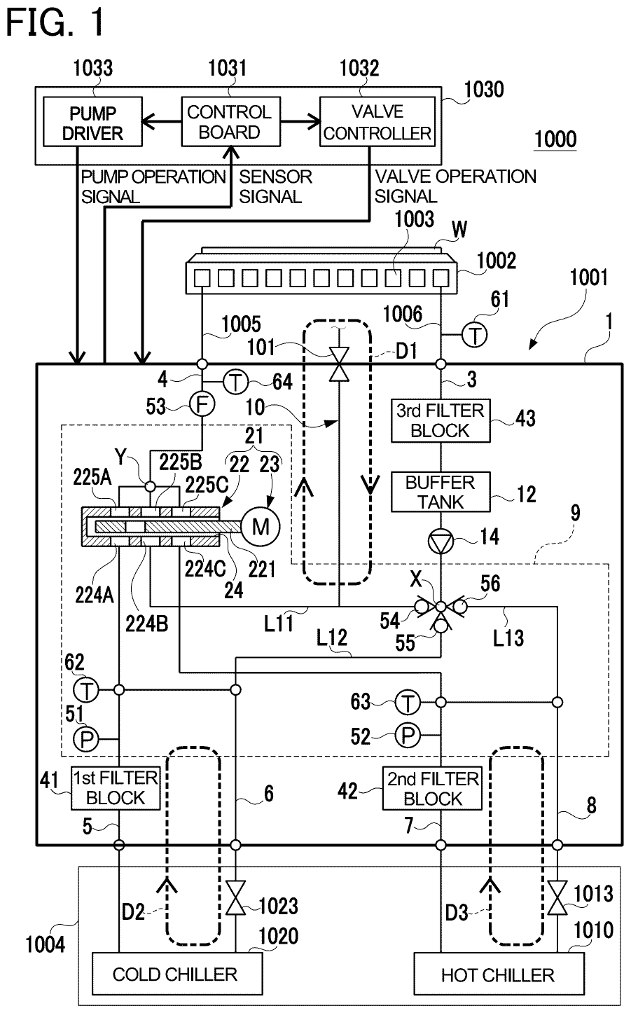

Firstly, the outline configuration of a flow rate control unit 1 for temperature regulation (hereinafter, also referred to as “unit 1”) using the spool valve 21 according to the present embodiment is described. FIG. 1 is a circuit diagram of the temperature-regulation flow rate control unit 1 using the spool valve 21 according to the present embodiment. This unit 1 will be used in a temperature control system 1001 for controlling the temperature of a semiconductor manufacturing device 1000, for example.

The semiconductor manufacturing device 1000 in the present embodiment is constituted as a RIE (Reactive Ion Etching) type plasma treatment device. The semiconductor manufacturing device 1000 controls the temperature of a wafer W disposed on a susceptor 1002 placed in a treatment vessel not shown to a predetermined temperature and performs an etching process on the wafer W.

For the etching process, two or more types of process gases are used and thus different treatment conditions for each process gas are set. Since the treatment conditions include the temperature of a wafer W to be treated, the temperature of the wafer W has to meet the treatment condition. For this purpose, the temperature of the susceptor 1002 that holds the wafer W is controlled by the temperature control system 1001.

The temperature control system 1001 includes a temperature regulation unit 1003 (hereinafter, simply referred to as a “temp-regulation unit 1003”), the unit 1, and a chiller unit 1004.

The temp-regulation unit 1003 is provided inside the susceptor 1002 and circulates a temperature regulation fluid discharged out of the unit 1 into the susceptor 1002. The temperature regulation fluid is a fluorine-type inert fluid that has little change in physical properties over a wide temperature range. The fluorine-type inert fluid is, for example, Fluorinert™ manufactured by 3M Japan Limited.

The chiller unit 1004 includes a cold chiller 1020 and a hot chiller 1010. The cold chiller 1020 is a device that circulates, between the chiller unit 1004 and the unit 1, a fluorine-type inert fluid controlled to a lower temperature than a set temperature for the temperature regulation fluid (hereinafter, a low-temperature fluid) in order to decrease the temperature of the temperature regulation fluid. The circulation pressure of the low-temperature fluid is controlled by a low-temperature side control valve 1023. The hot chiller 1010 is a device that circulates, between the chiller unit 1004 and the unit 1, a fluorine-type inert fluid controlled to a higher temperature than the set temperature for the temperature regulation fluid (hereinafter, a high-temperature fluid) in order to increase the temperature of the temperature regulation fluid. The circulation pressure of the high-temperature fluid is controlled by a high-temperature side control valve 1013. The temperatures of the above-described low-temperature fluid and high-temperature fluid are appropriately set according to the set temperature of a required temperature regulation fluid.

The unit 1 includes a first joint pipe 1005 for input of the temperature regulation fluid into the susceptor 1002 and a second joint pipe 1006 for output of the temperature regulation fluid after circulating through the susceptor 1002 (hereinafter, referred to as a post-circulation temperature regulation fluid). The unit 1 is connected to the susceptor 1002 via the first joint pipe 1005 and the second joint pipe 1006.

The unit 1 is provided with an output pipe 4 connected to the first joint pipe 1005, an input pipe 3 connected to the second joint pipe 1006, an input pipe for a low-temperature fluid 5 (a low-temperature-fluid input pipe) and an output pipe for a low-temperature fluid 6 (a low-temperature-fluid output pipe), through which the low-temperature fluid flows, an input pipe for a high-temperature fluid 7 (a high-temperature-fluid input pipe) and an output pipe for a high-temperature fluid 8 (a high-temperature-fluid output pipe), through which the high-temperature fluid flows, a pump 14 for circulating the temperature regulation fluid, a fluid control unit 9, and a control device 1030.

In the input pipe 3, a third filter block 43, a buffer tank 12, and the pump 14 are arranged in this order from an upstream side.

The post-circulation temperature regulation fluid enters from the second joint pipe 1006 to the input pipe 3. Here, a second temperature sensor 61 (one example of a second temperature measuring unit) is placed on the second joint pipe 1006 to measure the current temperature of the post-circulation temperature regulation fluid. The temperature control system 1001 obtains the current temperature of the susceptor 1002 by measuring the current temperature of the post-circulation temperature regulation fluid. Since the post-circulation temperature regulation fluid is a temperature regulation fluid having circulated through the susceptor 1002, its temperature can be equated with the temperature of the susceptor 1002. Further, the second temperature sensor 61, placed on the second joint pipe 1006, is located on an upstream side of the pump 14. Therefore, the second temperature sensor 61 can measure the temperature of the post-circulation temperature regulation fluid without being affected by heat generated by the pump 14. Although it is difficult to directly measure the temperature of a susceptor in the RIE type plasma treatment device due to the influences of plasmaized process gas, the temperature of the susceptor 1002 can be stably monitored by measuring the current temperature of the post-circulation temperature regulation fluid having circulated through the susceptor 1002.

The output pipe 4 outputs the temperature regulation fluid into the first joint pipe 1005. On the output pipe 4, a flow rate sensor 53 and a first temperature sensor 64 (one example of a first temperature measuring unit) are arranged in this order from an upstream side. The first temperature sensor 64 measures the temperature of the temperature regulation fluid to be discharged from the output pipe 4.

The fluid control unit 9 is connected to the temp-regulation unit 1003 via the input pipe 3 and the output pipe 4. Accordingly, as indicated by an arrowed broken line DI in FIG. 1, the temperature regulation fluid circulates between the temp-regulation unit 1003 and the fluid control unit 9.

The low-temperature-fluid input pipe 5 and the low-temperature-fluid output pipe 6 connect the fluid control unit 9 to the cold chiller 1020. Accordingly, as indicated by an arrowed broken line D2 in FIG. 1, the low-temperature fluid is inputted into and outputted from the fluid control unit 9. The temperature and the pressure of the low-temperature fluid inputted into the fluid control unit 9 are measured by a third temperature sensor 62 and a first pressure sensor 51, each placed on the low-temperature-fluid input pipe 5. Further, a first filter block 41 is placed on the low-temperature-fluid input pipe 5. This first filter block 41 removes foreign subjects from the low-temperature fluid inputted from the low-temperature-fluid input pipe 5 into the fluid control unit 9.

The high-temperature-fluid input pipe 7 and the high-temperature-fluid output pipe 8 connect the fluid control unit 9 to the hot chiller 1010. Accordingly, as indicated by an arrowed broken line D3 in FIG. 1, the high-temperature fluid is inputted into and outputted from the fluid control unit 9. The temperature and the pressure of the high-temperature fluid inputted into the fluid control unit 9 are measured by a fourth temperature sensor 63 and a second pressure sensor 52, each placed on the high-temperature-fluid input pipe 7. Further, a second filter block 42 is placed on the high-temperature-fluid input pipe 7. This second filter block 42 removes foreign subjects from the high-temperature fluid inputted from the high-temperature-fluid input pipe 7 into the fluid control unit 9.

The fluid control unit 9 has a branching section X that branches the input pipe 3 into a first branch line L11, a second branch line L12, and a third branch line L13. The first branch line L11 is connected to the spool valve 21. On this first branch line L11, a first check valve 54 is placed. Further, a purge mechanism 10 including a purge open/close valve 101 is connected to the first branch line L11 between the spool valve 21 and the first check valve 54. This purge open/close valve 101 is opened to supply purge air to the unit 1 during for example maintenance of the semiconductor manufacturing device 1000. The second branch line L12 is connected to the low-temperature-fluid output pipe 6. On this second branch line L12, a second check valve 55 is placed. The third branch line L13 is connected to the high-temperature-fluid output pipe 8. On this third branch line L13, a third check valve 56 is placed.

Each of the low-temperature-fluid input pipe 5, high-temperature-fluid input pipe 7, and first branch line L11 is connected to the spool valve 21. The spool valve 21 controls each flow rate (a flow distribution ratio) of the fluids supplied from the low-temperature-fluid input pipe 5, the high-temperature-fluid input pipe 7, and the first branch line L11, and discharges the fluids. Then, the fluids discharged from the spool valve 21 are mixed at a merging section Y and outputted into the output pipe 4 connected to the merging section Y. The configuration details of the spool valve 21 will be described later.

A fluid mixture mixed at the merging section Y and outputted into the output pipe 4 is the temperature regulation fluid for controlling the temperature of the susceptor 1002. In other words, the spool valve 21 adjusts the flow distribution rate of the post-circulation temperature regulation fluid inputted from the input pipe 3 into the spool valve 21, the low-temperature fluid inputted from the low-temperature-fluid input pipe 5 into the spool valve 21, and the high-temperature fluid inputted from the high-temperature-fluid input pipe 7 into the spool valve 21 to regulate the temperature of the temperature regulation fluid, and then outputs the fluid mixture into the output pipe 4.

Adjusting the flow contribution ratio (i.e., regulating the temperature of the temperature regulation fluid to be outputted into the output pipe 4) performed by the spool valve 21 is controlled based on a temperature control value created in the control device 1030 described later.

The valve opening degree of each of the first to third first check valves 54, 55, 56 is automatically adjusted according to the flow distribution ratio controlled by the spool valve 21. Accordingly, the post-circulation temperature regulation fluid is returned to the cold chiller 1020 and the hot chiller 1010 by approximately the same amount as the low-temperature fluid and the high-temperature fluid supplied to the spool valve 21.

The unit 1 is provided with the control device 1030 for controlling the operations of the temperature control system 1001. The control device 1030 is communicatively coupled to various sensors and valves of the unit 1. The control device 1030 includes a control board 1031, a pump driver 1033, and a valve controller 1032.

The control board 1031 creates a temperature control value for regulating the temperature regulation fluid to a desired set temperature. Further, the control board 1031 obtains, from the unit 1, the temperature measurement values measured by the temperature sensors 61, 62, 63, and 64 and the pressure measurement values measured by the first pressure sensor 51 and second pressure sensor 52, and creates a valve operation signal so that the temperature of the temperature regulation fluid is in line with the temperature control value, and transmits the created valve operation signal to the unit 1 via the valve controller 1032. In the unit 1, the spool valve 21 is operated according to the valve operation signal, adjusting the flow distribution ratio of the temperature regulation fluid, low-temperature fluid, and high-temperature fluid to regulate the temperature of the temperature regulation fluid to the set temperature. Thus, the temperature of the temperature regulation fluid is feed-back controlled and uniformized.

Further, the control board 1031 receives, from the unit 1, a flow measurement value measured by the flow rate sensor 53 and creates a pump operation signal to control the flow rate of the temperature regulation fluid to a desired set flow rate, and transmits it to the unit 1 via the pump driver 1033. In the unit 1, the pump 14 is operated according to the pump operation signal to adjust the flow rate of the temperature regulation fluid to the set flow rate. Thus, a circulation flow rate of the temperature regulation fluid is feed-back controlled and uniformized.

### Configuration of Spool Valve

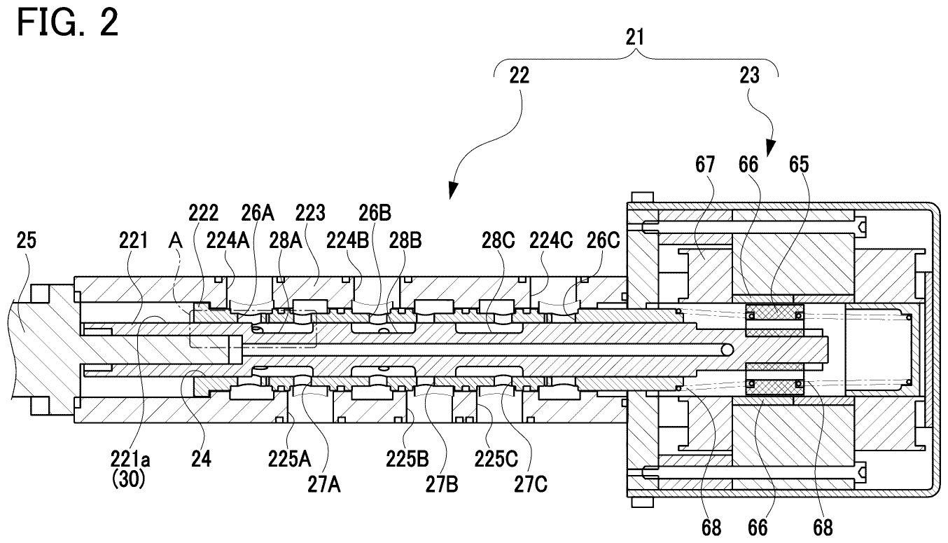

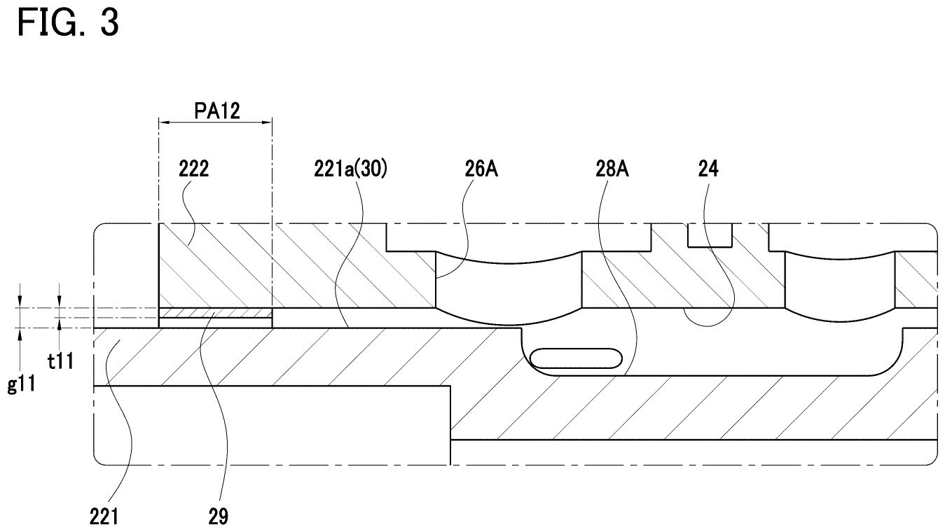

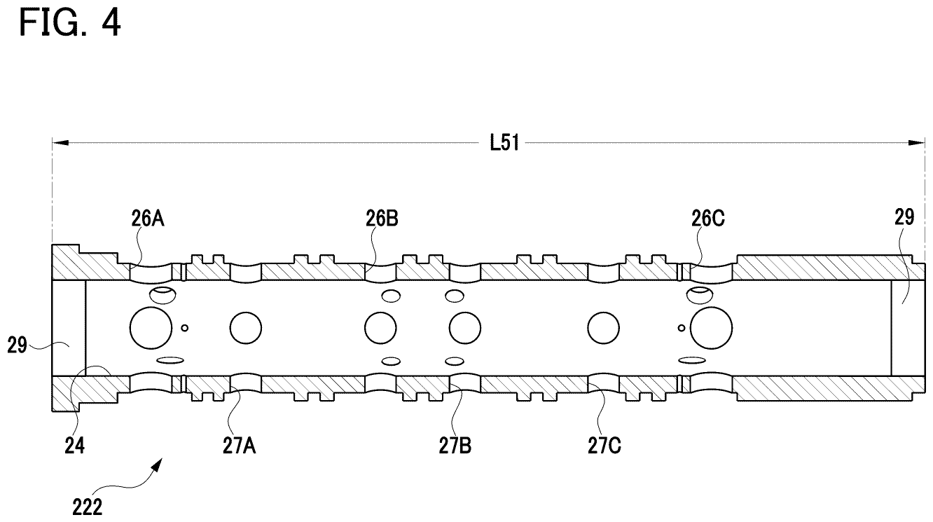

Next, the configuration of the spool valve 21 according to the present embodiment will be described in detail referring to the drawings. FIG. 2 is a cross-sectional view of the spool valve 21. FIG. 3 is a partial enlarged view of a part A in FIG. 2. FIG. 4 is a cross-sectional view showing the shape of a sleeve 222.

The spool valve 21 in the present embodiment includes, as shown in FIG. 2, a valve unit 22, a drive unit 23 connected to one of both ends of the valve unit in the axial direction, and a position sensor 25 connected to the other end of the valve unit 22.

The drive unit 23 is a linear actuator. The drive unit 23 includes a movable element 65 formed of ferromagnetic material, such as stainless steel, a pair of permanent magnets 66, 66 arranged with the movable element 65 interposed therebetween, and a coil 67 that generates a magnetic field in the same direction as the paired permanent magnets 66, 66. The movable element 65 is movable in a direction perpendicular to the field direction of the permanent magnets 66, 66, and is fixed to one end of a spool valve element 221 (described later) in the moving direction aligned with the sliding direction of the spool valve element 221. The position of the movable element 65 (i.e., the position of the spool valve element 221 in the axial direction (a stroke position)) is determined according to the energization direction and the magnitudes of voltage and current to the coil 67 based on the valve operation signal created by the control board 1031. The movable element 65 is held between springs 68 from both sides in the axial direction. Thus, when the coil 67 is not energized and a control fluid does not flow in the spool valve 21, the movable element 65 is held at the vicinity of a neutral position by the urging force of the springs 68 (that is, the stroke position is kept near the neutral position).

The valve unit 22 includes the spool valve element 221, the sleeve 222 slidably holding the spool valve element 221, and a body 223 in which the spool valve element 221 and the sleeve 222 are housed.

The body 223 is a case member having a nearly rectangular parallelepiped shape and including first body through holes 224A, 224B, 224C and second body through holes 225A, 225B, 225C, each of which provide communication between the inside and the outside of the body 223. The first body through hole 224A is connected to the low-temperature-fluid input pipe 5, allowing the low-temperature fluid to be supplied to the spool valve 21. The first body through hole 224B is connected to the first branch line L11, allowing the post-circulation temperature regulation fluid to be supplied to the spool valve 21. The first body through hole 224C is connected to the high-temperature-fluid input pipe 7, allowing the high-temperature fluid to be supplied to the spool valve 21. Furthermore, the second body through hole 225A allows the low-temperature fluid supplied to and flow-regulated by the spool valve 21 to be discharged from the spool valve 21. The second body through hole 225B allows the post-circulation temperature regulation fluid supplied to and flow-regulated by the spool valve 21 to be discharged from the spool valve 21. The second body through hole 225C allows the high-temperature fluid supplied to and flow-regulated by the spool valve 21 to be discharged from the spool valve 21. All the second body through holes 225A, 225B, 225C are connected to the merging section Y at which the fluids discharged from the spool valve 21 are mixed.

The sleeve 222 housed in the body 223 is made of stainless steel in a cylindrical shape. The sleeve 222 is internally provided with a valve chamber 24, through which the spool valve element 221 is placed.

Furthermore, the sleeve 222 includes input ports 26A, 26B, 26C, each of which is formed in the outer circumferential surface and communicates with the valve chamber 24. The input port 26A is placed at a position corresponding to the first body through hole 224A, the input port 26B is placed at a position corresponding to the first body through hole 224B, and the input port 26C is placed at a position corresponding to the first body through hole 224C. This configuration allows the fluid supplied into the spool valve 21 through the first body through holes 224A, 224B, 224C to flow in the valve chamber 24.

The sleeve 222 further includes output ports 27A, 27B, 27C, each of which is formed in the outer circumferential surface and communicates with the valve chamber 24. The output port 27A is placed at a position corresponding to the second body through hole 225A, the output port 27B is placed at a position corresponding to the second body through hole 225B, and the output port 27C is placed at a position corresponding to the second body through hole 225C. This configuration allows the fluid flowing in the valve chamber 24 to be discharged through the output ports 27A, 27B, 27C via the second body through holes 225A, 225B, 225C, respectively.

Further, as shown in FIG. 4, the sleeve 222 is provided with first surface treated portions 29, 29 treated with electroless nickel plating (one example of the first plating), on both end portions of the inner circumferential surface of the sleeve 222 (the valve chamber 24) in the axial direction. Thus, as shown in FIG. 3, the first surface treated portion 29 on the portion of the inner circumferential surface of the sleeve 222 (the valve chamber 24) has a smaller inner diameter just by the film thickness t11 of the electroless nickel plating than other portions of the inner circumferential surface of the sleeve 222 (the valve chamber 24). Accordingly, the first surface treated portions 29, 29 can aggressively support the spool valve element 221 that slides inside the sleeve 222 (the valve chamber 24), that is, support the spool valve element 221, at both end portions of the sleeve 222 in the axial direction. In this way, the place where the outer circumferential surface of the spool valve element 221 and the inner circumferential surface of the sleeve 222 (the valve chamber 24) interfere with each other during sliding of the spool valve element 221 is limited to the first surface treated portions 29, 29, and it is thus possible to suppress the occurrence of interference at multiple places. This can suppress the decrease in slidability of the spool valve element 221 and the occurrence of wear in the sleeve 222 or the spool valve element 221. The film thickness t11 in FIG. 2 does not represent the actual thickness, size, etc., for easy understanding, and therefore, is not necessarily limited to the size, and so on illustrated in the drawings.

The film thickness t11 of the electroless nickel plating is not particularly limited and, in the present embodiment, is about 3 to 25 μm. The electroless nickel plating of the first surface treated portion 29 is subjected to a backing process at 200° C. and its hardness is about 400 to 500 Hv in Vickers hardness. The temperature of the backing process is set at 200° C. in order to improve the adhesiveness of the plating and make it unlikely to peel off, but this setting is just one example. It is known that the hardness of electroless nickel plating becomes high as the temperature of the backing process is increased. Therefore, the temperature of the backing process can be adjusted according to the required hardness.

A plating range PA12 of the first surface treated portion 29 in the axial direction is appropriately set in a range of 1 mm or more, but 15% or less of the total length L51 (see FIG. 4) of the sleeve 222 in the axial direction, according to the sliding amount of the spool valve element 221.

The spool valve element 221 is made of stainless steel in a columnar shape. The spool valve element 221 is formed, on its outer circumferential surface, with spool circumferential grooves 28A, 28B, 28C arranged in the axial direction. The spool circumferential groove 28A extends over the entire periphery of the spool valve element 221 in the circumferential direction. The width of the spool circumferential groove 28A in the axial direction is set larger than a separation distance between the input port 26A and the output port 27A of the sleeve 222 in the axial direction.

When the spool circumferential groove 28A is at a position overlapping the input port 26A and the output port 27A, both the input port 26A and the output port 27A are communicated to the spool circumferential groove 28A and thus to each other through the spool circumferential groove 28A. This forms a series of flow passages from the first body through hole 224A to the second body through hole 225A via the input port 26A, spool circumferential groove 28A, and output port 27A. The overlapping width of the spool circumferential groove 28A with the input port 26A and the output port 27A increases or decreases according to the stroke position of the spool valve element 221. In other words, the open area of the input port 26A and the open area of the output port 27A are adjusted according to the stroke position of the spool valve element 221 and the flow rate of the fluid flowing in the above-described series of flow passages is controlled. When at least either the input port 26A or the output port 27A does not overlap the spool circumferential groove 28A, the above-described series of flow passages is blocked off. That is, the fluid is not allowed to flow through the above-described series of flow passages. The same applies to the relationship between the input port 26B, the output port 27B, and the spool circumferential groove 28B and the relationship between the input port 26C, the output port 27C, and the spool circumferential groove 28C.

The outer circumferential surface 221a of the spool valve element 221 has a uniform diameter throughout the axial direction, except for the portions formed with the spool circumferential grooves 28A, 28B, 28C. The outer diameter of this spool valve element 221 is set so that the gap g11 between the outer circumferential surface 221a of the spool valve element 221 and the inner circumferential surface of the sleeve 222 (the valve chamber 24) is 7 μm or more, but 55 μm or less. This is to suppress the fluid leakage (so-called internal leakage) due to the gap g11 while ensuring the slidability of the spool valve element 221. The gap g11 here is determined by dividing a difference between the diameter of the inner circumferential surface of the sleeve 222 and the diameter of the outer circumferential surface of the spool valve element 221 by 2, assuming that the spool valve element 221 is located coaxially with the sleeve 222.

If the gap g11 is larger than 55 μm, the internal leakage amount of the fluid may increase between the series of flow passages from the first body through hole 224A to the second body through hole 225A, the series of flow passages from the first body through hole 224B to the second body through hole 225B, and the series of flow passages from the first body through hole 224C to the second body through hole 225C. To suppress the internal leakage, it is conceivable to minimize the gap g11. However, if the size of the gap g11 is smaller than 7 μm, the sleeve 222 and the spool valve element 221 may interfere with each other, resulting in a decrease in slidability of the spool valve element 221. On this account, the gap g11 is set to 7 μm or more, but 55 μm or less as described above.

Furthermore, the outer circumferential surface 221a of the spool valve element 221 including the spool circumferential grooves 28A, 28B, 28C is a second surface treated portion 30 entirely surface-treated with electrolytic plating (concretely, hard chrome plating (one example of a second plating)). The hardness of this hard chrome plating is about 800 Hv in Vickers hardness.

During sliding of the spool valve element 221 inside the valve chamber 24, the first surface treated portion 29 aggressively supports the spool valve element 221, the first surface treated portion 29 and the second surface treated portion 30 (the outer circumferential surface 221a of the spool valve element 221) rub against each other. Meanwhile, the first surface treated portion 29 of the sleeve 222 is formed by electroless nickel plating, whereas the second surface treated portion 30 is formed by hard chrome plating. Further, the hardness of the first surface treated portion 29 is 400 to 500 Hv in Vickers hardness, whereas the hardness of the second surface treated portion 30 is about 800 Hv in Vickers hardness, which is higher than that of the first surface treated portion 29. Specifically, plating films formed of dissimilar materials and with different hardness rub against each other. This can suppress galling of the plating films and hence suppress a decrease in slidability of the spool valve element.

The plating process on the inner circumferential surface of the sleeve 222 is not easy, but the plating process on the outer circumferential surface of the spool valve element 221 is relatively easy. Accordingly, as described above, the first surface treated portion 29 is treated with electroless nickel plating, which is easy to control the film thickness, but high in cost, and the second surface treated portion 30 is treated with hard chrome plating, which is lower in cost than the electroless plating, to achieve appropriate manufacturing costs.

The position sensor 25 is a sensor for detecting the stroke position of the spool valve element 221. Based on a detection result of this position sensor 25, the stroke position can be feed-back controlled. The position sensor 25 may be a magnetostrictive sensor, for example.

As described above, (1) the spool valve 21 in the present embodiment is provided with the cylindrical sleeve 222, the sleeve 222 including two or more input ports 26A, 26B, 26C and two or more output ports 27A, 27B, 27C, each communicating to the inside of the sleeve 222, and the spool valve element 221 slidable inside the sleeve 222 in the axial direction of the sleeve 222. The open areas of the input ports 26A, 26B, 26C and output ports 27A, 27B, 27C are adjusted by sliding of the spool valve element 221. In the spool valve 21, at least one of the sleeve 222 and the spool valve element 221 includes, at both end portions in the axial direction of the sleeve 222, the support portions for supporting the sliding of the spool valve element 221 by reducing the gap g11 between the inner circumferential surface of the sleeve 222 and the outer circumferential surface of the spool valve element 221 than at other portions.

(2) In the spool valve 21 described in (1), preferably, the sleeve 222 includes the first surface treated portions 29 treated with the first plating (e.g., electroless nickel plating), which are provided on both end portions of the inner circumferential surface in the axial direction, and each first surface treated portion 29 is the support portion.

According to the spool valve 21 described in above (1) and (2), the sleeve 222 includes, at both end portions in the axial direction of the sleeve 222, the support portions (the first surface treated portions 29) for supporting the sliding of the spool valve element by reducing the gap between the inner circumferential surface of the sleeve 222 and the outer circumferential surface of the spool valve element 221, compared to at other portions, so that the support portions (the first surface treated portions 29) can aggressively support the spool valve element 221. The term “support/supporting” here does not mean fixing the spool valve element 221, but simply guiding the sliding of the spool valve element 221 without causing the interference of the spool valve element 221 with the inner circumferential surface of the sleeve 222 at any places other than the support portion(s) (first surface treated portion(s) 29). That is, the place where the outer circumferential surface of the spool valve element 221 interferes with the inner circumferential surface of the sleeve 222 is limited to the support portion(s) (first surface treated portion(s) 29), and it is possible to suppress the occurrence of the interference at multiple places. This can suppress the decrease in slidability of the spool valve element 221 and reduce the occurrence of wear in the sleeve 222 or the spool valve element 221.

(4) In the spool valve 21 described in (2), preferably, the support portions (the first surface treated portions 29) each have the width (a plating range PA12) of 1 mm or more in the axial direction, but 15% or less of the total length L51 of the sleeve 222 in the axial direction. This is because if the width of each support portion (each first surface treated portion 29) is smaller than 1 mm, that is, if the surface area of each support portion (each first surface treated portion 29) that supports the spool valve element 221 is small, the stress per unit area is large, causing wear of the support portion (the first surface treated portion 29) due to sliding of the spool valve element 221. Such a wear is undesirable because it may impede the sliding of the spool valve element 221. Furthermore, if the width of each support portion (each first surface treated portion 29) is smaller than 1 mm, it is undesirable because the surface treatment such as plating (e.g., electroless nickel plating) cannot be achieved with a stable quality. If the width (a plating range PA12) of each support portion (each first surface treated portion 29) is larger than 15% of the total length L51 of the sleeve, that is, if the surface area of each support portion (each first surface treated portion 29) that supports the spool valve element 221 is large, the spool valve element 221 and the support portion (the first surface treated portion 29) may contact each other at many contact points due to processing strain that occurs in the spool valve element 221 and the sleeve 222. If many contact points occur between the spool valve element 221 and the support portion (the first surface treated portion 29), the effect of suppressing the decrease in slidability of the spool valve element 221 and the effect of suppressing the occurrence of wear in the sleeve 222 or spool valve element 221 could not be achieved sufficiently.

(5) In the spool valve 21 described in (2), preferably, the spool valve element 221 includes the second surface treated portion 30 treated with the second plating (e.g., hard chrome plating) on at least a portion of the outer circumferential surface facing the first surface treated portions 29, and the hardness of the second plating (hard chrome plating) (e.g., about 800 Hv in Vickers hardness) is higher than the hardness of the first plating (electroless nickel plating) (e.g., 400 to 500 Hv in Vickers hardness).

The inventors have experimentally confirmed that when the first plating and the second plating are set equal in hardness, a galling phenomenon of the plating films may occur during sliding of the spool valve element 221. This galling phenomenon may decrease the slidability of the spool valve element 221. Under such circumstances, the inventors have experimentally confirmed that when the hardness of the second plating (hard chrome plating) on the outer circumferential surface of the spool valve element 221 is set higher than the hardness of the first plating (electroless nickel plating) on the inner circumferential surface of the sleeve 222 as in the spool valve 21 described in (5), it is possible to prevent the occurrence of the galling phenomenon and hence suppress the decrease in slidability of the spool valve element 221.

(6) In the spool valve 21 described in (5), preferably, the first plating is electroless plating (electroless nickel plating), and the second plating is electrolytic plating (hard chrome plating).

For dimensional control of the gap g11 between the outer circumferential surface (the outer diameter) of the spool valve element 221 and the inner circumferential surface (the inner diameter) of the sleeve 222, it is important that each of the first surface treated portion 29 and the second surface treated portion 30 respectively have uniform film thicknesses. For finishing to the specified inner and outer diameters after plating, a means for dimensional adjustment in post-processing, such as polishing a plated surface, may be adopted. At that time, the outer diameter of the spool valve element 221 is easy to adjust by processing, such as outer diameter polishing, but the inner diameter of the sleeve 222 is hard to process. Therefore, as in the spool valve 21 described in (5), the outer circumferential surface of the spool valve element 221 is treated with the electrolytic plating (the second plating) that is apt to have a non-uniform film thickness and the inner circumferential surface of the sleeve 222 is treated with the electroless plating (the first plating) that is easy to have a uniform film thickness, so that the size of the gap g11 can be controlled appropriately. Moreover, the inventors experimentally confirmed that the first plating and the second plating applied by dissimilar material treatment could prevent the occurrence of the galling phenomenon during sliding of the spool valve element 221.

(7) In the spool valve 21 described in (1) to (6), preferably, in the temperature-regulation flow rate control unit 1 for regulating the temperature of the susceptor 1002 provided in the semiconductor manufacturing device 1000 by circulating a temperature regulation fluid to the susceptor 1002, the spool valve 21 regulates the temperature of the temperature regulation fluid by adjusting the output flow rate of the low-temperature fluid for decreasing the temperature of the temperature regulation fluid, the low-temperature fluid being inputted in the input port 26A, which is one of the two or more input ports, and outputted from the output port 27A, which is one of the two or more output ports, and the output flow rate of the high-temperature fluid for increasing the temperature of the temperature regulation fluid, the high-temperature fluid being inputted in the input port 26C, which is one of the two or more input ports, and outputted from the output port 27C, which is one of the two or more output ports, and the gap g11 between the outer circumferential surface of the spool valve element 221 and the inner circumferential surface excepting the first surface treated portions 29 is 7 μm or more, but 55 μm or less.

To suppress fluid leakage (so-called internal leakage) due to the gap g11 between the inner circumferential surface of the sleeve 222 and the outer circumferential surface of the spool valve element 221, it is necessary to seal between the inner circumferential surface of the sleeve 222 and the outer circumferential surface of the spool valve element 221. However, this sealing leads to decreased slidability of the spool valve element 221. The responsiveness is important for the spool valve 21 used in the temperature-regulation flow rate control unit 1, and thus the decreased slidability of the spool valve element 221 due to the sealing is undesirable. In order to reduce the internal leakage to the minimum without the sealing, it is conceivable to minimize the gap g11 between the inner circumferential surface of the sleeve 222 and the outer circumferential surface of the spool valve element 221. However, if the gap is too small, the sleeve 222 and the spool valve element 221 may interfere with each other, resulting in the decreased slidability of the spool valve element 221. Therefore, the spool valve element 221 is supported by the first surface treated portions 29 and additionally the gap g11 between the outer circumferential surface of the spool valve element 221 and the inner circumferential surface of the sleeve 222 excluding the first surface treated portions 29 is set to 7 μm or more, but 55 μm or less, as in the spool valve described in (7). This configuration can suppress the internal leakage of the high-temperature fluid and the low-temperature fluid while ensuring the slidability of the spool valve element 221.

### Second Embodiment

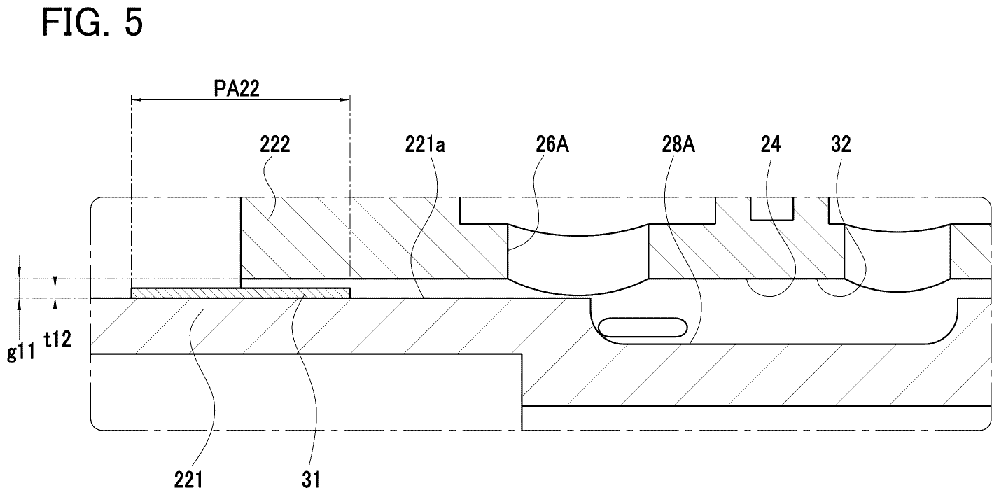

Next, a spool valve of a second embodiment will be described on only differences from the first embodiment. FIG. 5 is a partial enlarged view of the spool valve of the second embodiment, similar to FIG. 3.

In the spool valve of the second embodiment, a spool valve element 221 includes support portions for supporting sliding of the spool valve element 221. The support portions are each composed of a surface treated portion 31 treated with electrolytic plating, formed on each of portions of the outer circumferential surface of the spool valve element 221, facing both end portions of the inner circumferential surface of the sleeve 222 in the axial direction. The surface treated portion 31 (the support portion) can support the sliding of the spool valve element 221 by reducing the gap g11 at both end portions in the axial direction of the sleeve 222 than at other portions.

The film thickness t12 of the electrolytic plating is not particularly limited, but is about 3 to 25 μm in the present embodiment. Further, a plating range PA22 of each of the surface treated portions 31 in the axial direction is set appropriately, taking into account tolerances and other factors, to a minimum of twice of the sliding distance of the spool valve element 221 in the axial direction.

The inner circumferential surface of the sleeve 222 is a surface treated portion 32 entirely treated with electroless nickel plating. This electroless nickel plating is subjected to a backing process at 200° C. and its hardness is about 400 to 500 Hv in Vickers hardness. The temperature of the backing process is set at 200° C. in order to improve the adhesiveness of the plating and make it unlikely to peel off, but this is just one example. It is known that the hardness of electroless nickel plating becomes high as the temperature of the backing process is increased. Therefore, the temperature of the backing process can be adjusted according to the required hardness.

This configuration that the spool valve element 221 includes the support portions (the surface treated portions 31) for supporting the sliding of the spool valve element can also limit the interference place where the outer circumferential surface of the spool valve element 221 and the inner circumferential surface of the sleeve 222 interfere with each other to the support portion(s) (surface treated portion(s) 31), and can suppress the occurrence of interference at multiple places. This can suppress the decrease in slidability of the spool valve element 221 and suppress the occurrence of wear in the sleeve 222 or the spool valve element 221.

### Third Embodiment

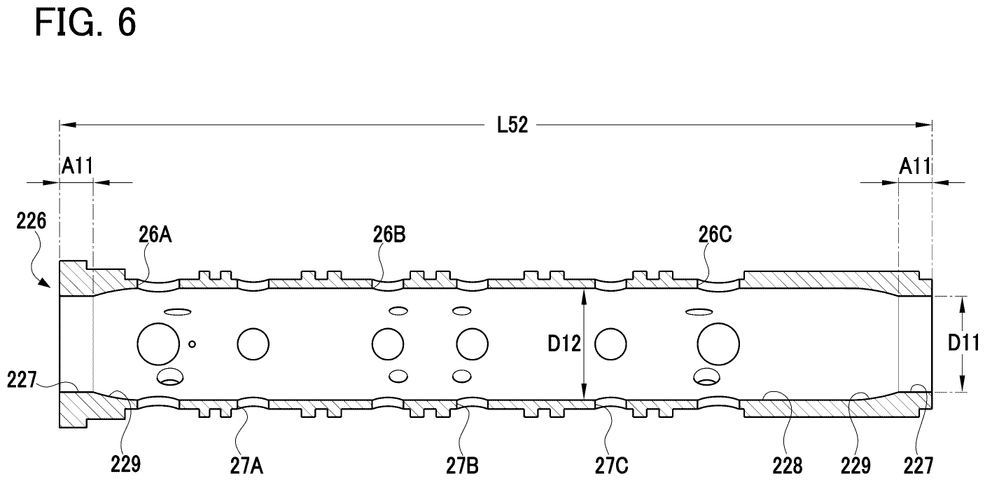

Next, a spool valve of a third embodiment will be described on only differences from the first embodiment. FIG. 6 is a cross-sectional view of the spool valve of the third embodiment, showing the shape of a sleeve 226. The referenced drawing is deformed for easy description and does not accurately represent shapes and dimensions.

The sleeve 226 has an inner circumferential surface 228 whose diameter is gradually reduced outward in the axial direction by sloped portions 229, at both end portions in the axial direction. Thus, the sleeve 226 includes support portions 227 formed at both end portions in the axial direction. Since the support portions 227 are formed as above, the spool valve element 221 inserted in the sleeve 226 is aggressively supported by the support portions 227. Accordingly, the interference place where the spool valve element 221 and the sleeve 226 interfere with each other is limited to the support portion(s) 227, and it is possible to suppress the occurrence of interference at multiple places. The spool valve element 221 of this embodiment is identical to the spool valve element 221 of the first embodiment.

At that time, the reduced amount of diameter, that is, a value obtained by subtracting the inner diameter D11 of each support portion 227 from a value of the inner diameter D12 of the sleeve 226 is preferably 4 μm or more, but 60 μm or less. This is because if the diameter reduction amount is less than 4 μm, the spool valve element 221 is not sufficiently supported, which may cause interference at a place other than the support portions 227. In contrast, if the diameter reduction amount is more than 60 μm, the internal fluid leakage may occur between the inner circumferential surface 228 of the sleeve 226 and the spool valve element 221.

Further, the width All of each support portion 227 in the axial direction is preferably 2% or more, but 15% or less of the total length L51 of the sleeve 226 in the axial direction. This is because if the width All of the support portion 227 is smaller than 2% of the total length L52 of the sleeve 226, that is, if the surface area of the support portion 227 that supports the spool valve element 221 is small, the stress per unit area is large, which may cause the occurrence of wear of the support portion 227 due to sliding of the spool valve element 221. The occurrence of wear is not desirable because it may impede the sliding of the spool valve element 221. In addition, if the width All of each support portion 227 in the axial direction is smaller than 2% of the total length L52 of the sleeve in the axial direction, it is undesirable because the surface treatment of plating (e.g., electroless nickel plating) cannot be achieved with a stable quality. In contrast, if the width All of the support portion 227 is larger than 15% of the total length L52 of the sleeve 226, that is, if the surface area of the support portion 227 supporting the spool valve element 221 is large, the spool valve element 221 and the support portions 227 may contact each other at many contact points due to processing strain that occurs in the spool valve element 221 and the sleeve 226. If many contact points occur between the spool valve element 221 and each support portion 227, the effect of suppressing the decrease in slidability of the spool valve element 221 and the effect of suppressing the occurrence of wear in the sleeve 226 or spool valve element 221 could not be achieved sufficiently.

In the present embodiment, the entire inner circumferential surface of the sleeve 226 including the support portions 227 and the sloped portions 229 is surface-treated with electroless nickel plating. In contrast, the entire outer circumferential surface of the spool valve element 221 to be inserted in the sleeve 226 is surface-treated with electrolytic plating (hard chrome plating).

The foregoing embodiments are mere examples and give no limitation to the present disclosure. The present disclosure may be embodied in other specific forms without departing from the essential characteristics thereof. For example, the above-described embodiments exemplify that the spool valve 21 is used in the semiconductor manufacturing device 1000; however, the spool valve 21 may be used in any devices other than the semiconductor manufacturing device 1000.

### REFERENCE SIGNS LIST

21 Spool valve
26A Input port
26B Input port
26C Input port
27A Output port
27B Output port
27C Output port
29 First surface treated portion
221 Spool valve element
222 Sleeve

1. A spool valve comprising:
a cylindrical sleeve,
the sleeve including two or more input ports and two or more output ports, each communicating with inside of the sleeve; and
a spool valve element that slides inside the sleeve in an axial direction of the sleeve,
an open area of each of the input ports and the output ports being adjusted by sliding of the spool valve element,
wherein at least one of the sleeve and the spool valve element comprises, at each of both end portions in the axial direction of the sleeve, a support portion for supporting the sliding of the spool valve element by reducing a gap between an inner circumferential surface of the sleeve and an outer circumferential surface of the spool valve element than at other portions.

2. The spool valve described in claim 1, wherein
the sleeve includes a first surface treated portion treated with first plating in each of both end portions of the inner circumferential surface in the axial direction, and
the first surface treated portion is the support portion.

3. The spool valve described in claim 1, wherein
the spool valve element includes a surface treated portion treated with electrolytic plating, in each of portions of the outer circumferential surface facing both end portions of the inner circumferential surface of the sleeve in the axial direction, and
the surface treated portion is the support portion.

4. The spool valve described in claim 2, wherein the support portion has a width of 1 mm or more in the axial direction, but 15% or less of a total length of the sleeve in the axial direction.

5. The spool valve described in claim 2, wherein
the spool valve element includes a second surface treated portion treated with second plating, on at least a portion of the outer circumferential surface facing the first surface treated portion, and
the second plating has a hardness higher than a hardness of the first plating.

6. The spool valve described in claim 5, wherein
the first plating is electroless plating, and
the second plating is electrolytic plating.

7. The spool valve described in claim 1, wherein
in a flow rate control unit for temperature regulation, that regulates a temperature of a susceptor provided in a semiconductor manufacturing device by circulating a temperature regulation fluid to the susceptor,
the spool valve regulates
an output flow rate of a low-temperature fluid for reducing the temperature of the temperature regulation fluid, the low-temperature fluid being inputted in a first input port, which is one of the two or more input ports, and outputted from a first output port, which is one of the two or more output ports, and
an output flow rate of a high-temperature fluid for increasing the temperature of the temperature regulation fluid, the high-temperature fluid being inputted in a second input port, which is one of the two or more input ports, and outputted from a second output port, which is one of the two or more output ports, to regulate the temperature of the temperature regulation fluid, and
the gap excluding a reduced area by the support portions is 7 μm or more, but 55 μm or less.

8. The spool valve described in claim 1, wherein
the sleeve includes the support portion formed with a reduced inner diameter, on each of both end portions of the inner circumferential surface in the axial direction, and
a reduced amount of the inner diameter of the support portion is 4 μm or more, but 60 μm or less.

9. The spool valve described in claim 8, wherein the support portion has a width in the axial direction that is 2% or more, but 15% or less of a total length of the sleeve in the axial direction.

10. The spool valve described in claim 2, wherein
in a flow rate control unit for temperature regulation, that regulates a temperature of a susceptor provided in a semiconductor manufacturing device by circulating a temperature regulation fluid to the susceptor,
the spool valve regulates
an output flow rate of a low-temperature fluid for reducing the temperature of the temperature regulation fluid, the low-temperature fluid being inputted in a first input port, which is one of the two or more input ports, and outputted from a first output port, which is one of the two or more output ports, and
an output flow rate of a high-temperature fluid for increasing the temperature of the temperature regulation fluid, the high-temperature fluid being inputted in a second input port, which is one of the two or more input ports, and outputted from a second output port, which is one of the two or more output ports,
to regulate the temperature of the temperature regulation fluid, and
the gap excluding a reduced area by the support portions is 7 μm or more, but 55 μm or less.

11. The spool valve described in claim 3, wherein
in a flow rate control unit for temperature regulation, that regulates a temperature of a susceptor provided in a semiconductor manufacturing device by circulating a temperature regulation fluid to the susceptor,
the spool valve regulates
an output flow rate of a low-temperature fluid for reducing the temperature of the temperature regulation fluid, the low-temperature fluid being inputted in a first input port, which is one of the two or more input ports, and outputted from a first output port, which is one of the two or more output ports, and
an output flow rate of a high-temperature fluid for increasing the temperature of the temperature regulation fluid, the high-temperature fluid being inputted in a second input port, which is one of the two or more input ports, and outputted from a second output port, which is one of the two or more output ports,
to regulate the temperature of the temperature regulation fluid, and
the gap excluding a reduced area by the support portions is 7 μm or more, but 55 μm or less.

12. The spool valve described in claim 4, wherein
in a flow rate control unit for temperature regulation, that regulates a temperature of a susceptor provided in a semiconductor manufacturing device by circulating a temperature regulation fluid to the susceptor,
the spool valve regulates
an output flow rate of a low-temperature fluid for reducing the temperature of the temperature regulation fluid, the low-temperature fluid being inputted in a first input port, which is one of the two or more input ports, and outputted from a first output port, which is one of the two or more output ports, and
an output flow rate of a high-temperature fluid for increasing the temperature of the temperature regulation fluid, the high-temperature fluid being inputted in a second input port, which is one of the two or more input ports, and outputted from a second output port, which is one of the two or more output ports, to regulate the temperature of the temperature regulation fluid, and
the gap excluding a reduced area by the support portions is 7 μm or more, but 55 μm or less.

13. The spool valve described in claim 5, wherein
in a flow rate control unit for temperature regulation, that regulates a temperature of a susceptor provided in a semiconductor manufacturing device by circulating a temperature regulation fluid to the susceptor,
the spool valve regulates
an output flow rate of a low-temperature fluid for reducing the temperature of the temperature regulation fluid, the low-temperature fluid being inputted in a first input port, which is one of the two or more input ports, and outputted from a first output port, which is one of the two or more output ports, and
an output flow rate of a high-temperature fluid for increasing the temperature of the temperature regulation fluid, the high-temperature fluid being inputted in a second input port, which is one of the two or more input ports, and outputted from a second output port, which is one of the two or more output ports,
to regulate the temperature of the temperature regulation fluid, and
the gap excluding a reduced area by the support portions is 7 μm or more, but 55 μm or less.

14. The spool valve described in claim 6, wherein
in a flow rate control unit for temperature regulation, that regulates a temperature of a susceptor provided in a semiconductor manufacturing device by circulating a temperature regulation fluid to the susceptor,
the spool valve regulates
an output flow rate of a low-temperature fluid for reducing the temperature of the temperature regulation fluid, the low-temperature fluid being inputted in a first input port, which is one of the two or more input ports, and outputted from a first output port, which is one of the two or more output ports, and
an output flow rate of a high-temperature fluid for increasing the temperature of the temperature regulation fluid, the high-temperature fluid being inputted in a second input port, which is one of the two or more input ports, and outputted from a second output port, which is one of the two or more output ports,
to regulate the temperature of the temperature regulation fluid, and
the gap excluding a reduced area by the support portions is 7 μm or more, but 55 μm or less.
